(19) United States
(12) Patent Application Publication
(10) Pub. No.: US 2004/0051138 A1
(43) Pub. Date: Mar. 18, 2004

(54) MOSFET with low leakage current and fabrication method thereof

(76) Inventor: Wen-Yueh Jang, Hsinchu (TW)

Correspondence Address: POWELL, GOLDSTEIN, FRAZER & MURPHY LLP, P.O. BOX 97223, WASHINGTON, DC, 20090-7223, US

(21) Appl. No.: 10/244,533

(22) Filed: Sep. 17, 2002

(51) Int. Cl. H01L 29/76; H01L 21/336

(52) U.S. Cl. 257/345; 438/282; 257/349; 438/298

(57) ABSTRACT

A MOSFET with low leakage current and method. The MOSFET has a substrate, a channel region, a source/drain region, a gate oxide layer and a conductive layer. The channel region in the substrate has a first region and a second region. The first region has a first threshold voltage and the second region has a second threshold voltage, respectively. The second region is located between the first region and the source/drain region. The first threshold voltage is smaller than the second threshold voltage. The leakage current of the MOSFET has an appropriate reduction by increasing the second threshold voltage of the second region. Significantly, by adjusting the size and position of the second region of the channel region, both the leakage current and the drain current of the MOSFET are readily optimized.

### FIELD OF THE INVENTION

The present invention generally relates to semiconductor structures and processes, and more particularly, to a MOSFET with a low leakage current and a manufacturing method for the same.

### BACKGROUND OF THE INVENTION

With the rapid shrinkage of integrated circuits (ICs), a short channel effect occurs, leading to high power consumption due to a leakage current in the ICs. Additionally, a lower power supply voltage is applied to the ICs to save power consumption. But, higher drain current requires a decrement of the threshold voltage. It also increases largely the leakage current of the ICs.

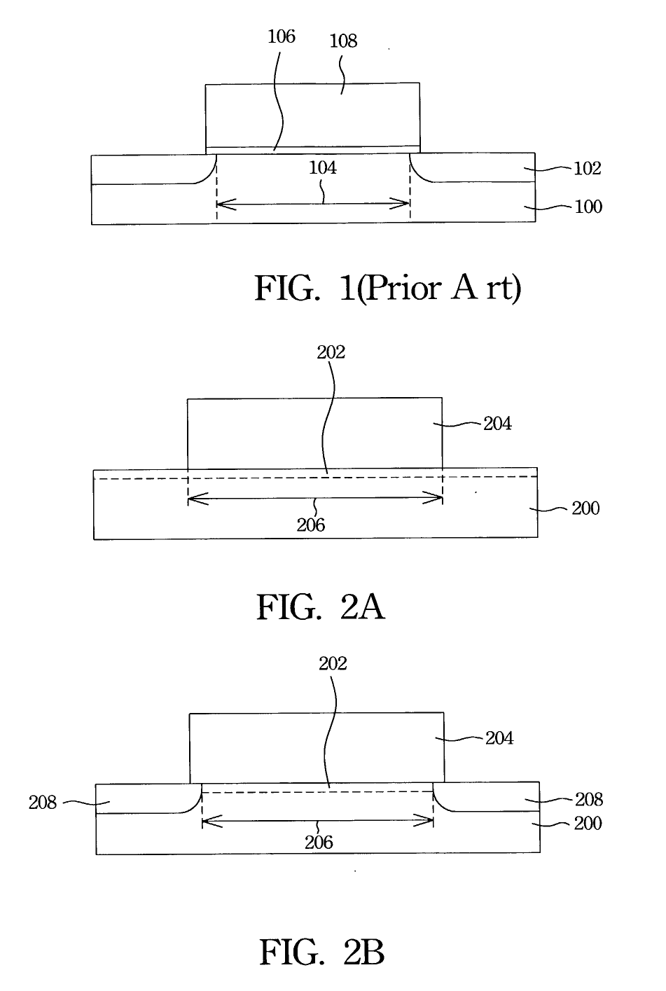

Specifically, to solve these problems of the short channel effects, an increment of threshold voltage has been developed. FIG. 1 shows a schematic, cross-sectional view of a conventional MOSFET. A source/drain 102 is formed on a substrate 100 and a channel region 104 is located between the source and the drain 102. A gate oxide layer 106 and a gate conductive layer 108 are deposited on the channel region 104.

However, a doping concentration of channel region 104 is from 5×10¹⁶ cm⁻² to 1×10¹⁸ cm⁻², and merely has a single doping. As a result of the single doping, the subthreshold leakage current is difficult to reduce. On the other hand, high threshold voltage will decrease the drain current and lead to a poor performance of the MOSFET.

Consequently, how to adjust the channel region, to reduce the subthreshold leakage current and to improve the drain current in the MOSFET are important problems and are currently main issues for semiconductor manufacturers.

### SUMMARY OF THE INVENTION

One object of the present invention is to utilize a MOSFET with low leakage current and manufacturing method to decrease the subthreshold leakage current by increasing the doping concentration of a portion of the channel region of the MOSFET.

Another object of the present invention is to use a MOSFET with low leakage current and manufacturing method to optimize both the subthreshold leakage current and the drain current by adjusting the position and size of the channel region.

According to the above objects, the present invention sets forth a MOSFET with low leakage current and manufacturing method.

A first ion implantation is performed on a substrate to generate a first threshold voltage. Thereafter, a channel region is defined on the substrate by a sacrificial layer. A source/drain implanted in the substrate adjoins the channel region. A first dielectric layer is deposited on the substrate and the sacrificial layer and then a portion of first dielectric layer stripped away. An opening is formed in the sacrificial layer to expose the channel region. The first ion implantation can also be performed after this step. Afterwards, a second dielectric layer is deposited on the first dielectric layer and the channel region.

Performing an anisotropic etching on the second dielectric layer creates spacers connected to the sidewall of the opening and the first region of the channel region is exposed. A third dielectric layer is formed on the first dielectric layer, spacers and the first region. A portion of the third dielectric layer is removed and a portion of the spacers is exposed. Next, another portion of the channel region is exposed to define a second region, in which the second region is connected to the first region and to the source/drain.

A second ion implantation is performed and another portion of the channel region is exposed. The second region to which the source/drain is adjacent has a second threshold voltage. More importantly, the first threshold voltage of the first region is smaller than the second threshold voltage of the second region. The second region is located between the first region and the source/drain. The third dielectric layer is removed and a gate oxide layer is formed on the channel region of the exposed substrate.

A conductive layer formed on the gate oxide layer and the first dielectric layer is higher than the first dielectric layer. Subsequently, a portion of the conductive layer is removed to expose the first dielectric layer to generate a MOSFET with low leakage current.

In the present invention, due to the first and the second ion implantation, the second region has a higher doping than the first region so that the second threshold voltage is higher than the second threshold voltage. Also, by adjusting the length of the second region along the channel region, the influence of the second threshold voltage applied to the drain current is considerably reduced to stabilize the variation of the drain current.

Further, by changing the position of the second region and adjusting the relative position between the second region and the source/drain, the effective channel length of the second region along the channel region is allowed to be properly increased. The flexibility between the leakage current and the drain current is thus improved.

In summary, the present invention utilizes a MOSFET with low leakage current. The channel region of the MOSFET is divided into several portions with a variety of doping concentrations. By adjusting the threshold voltage, length and the position of the portions, the leakage current and the drain current are mutually optimized.

### BRIEF DESCRIPTION

The foregoing aspects and many of the attendant advantages of this invention will become more readily appreciated as the same becomes better understood by reference to the following detailed description when taken in conjunction with the accompanying drawings, wherein:

FIG. 1 illustrates a schematic, cross-sectional view of a conventional MOSFET; and

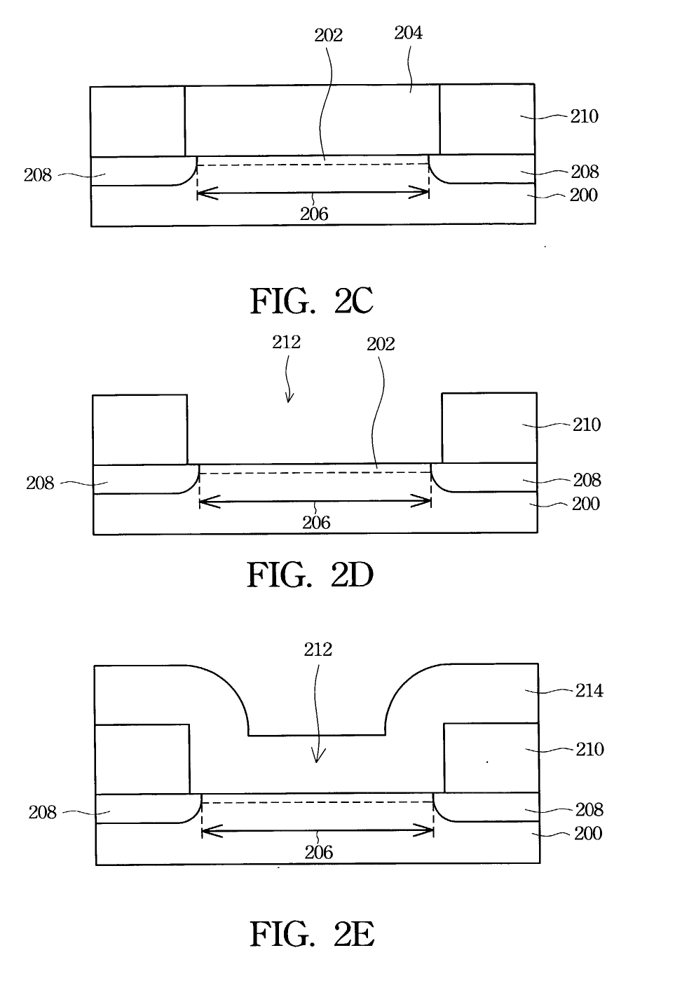

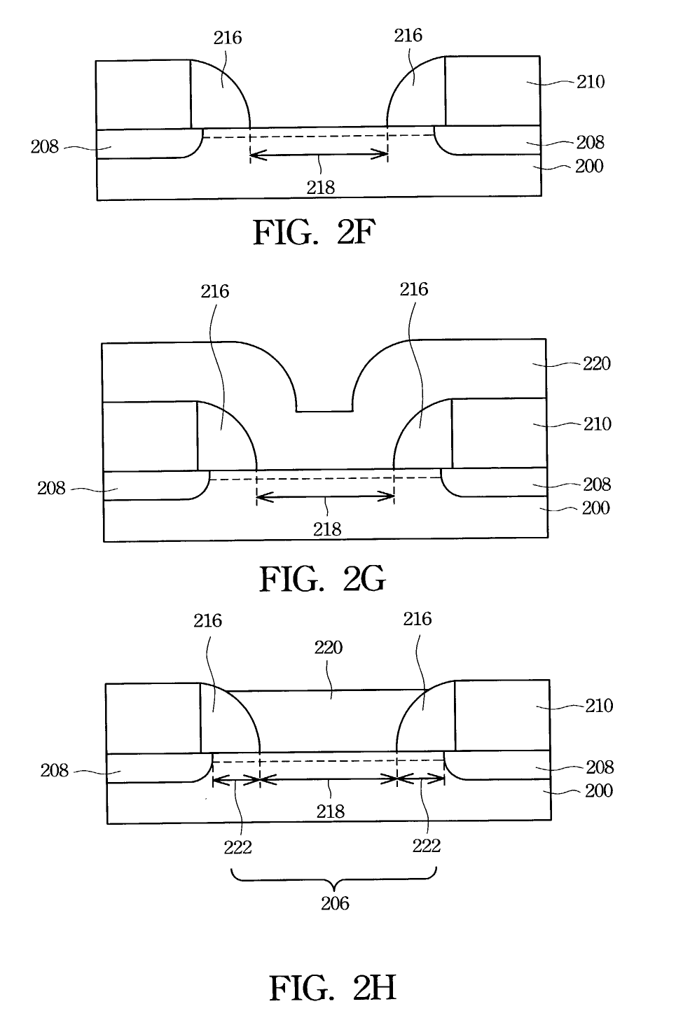

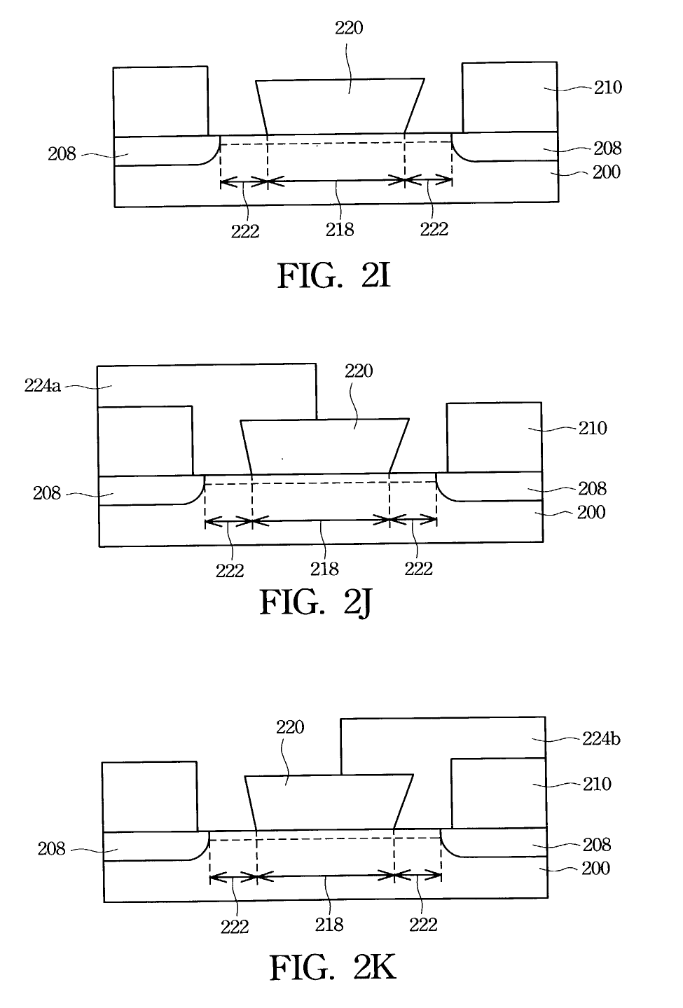

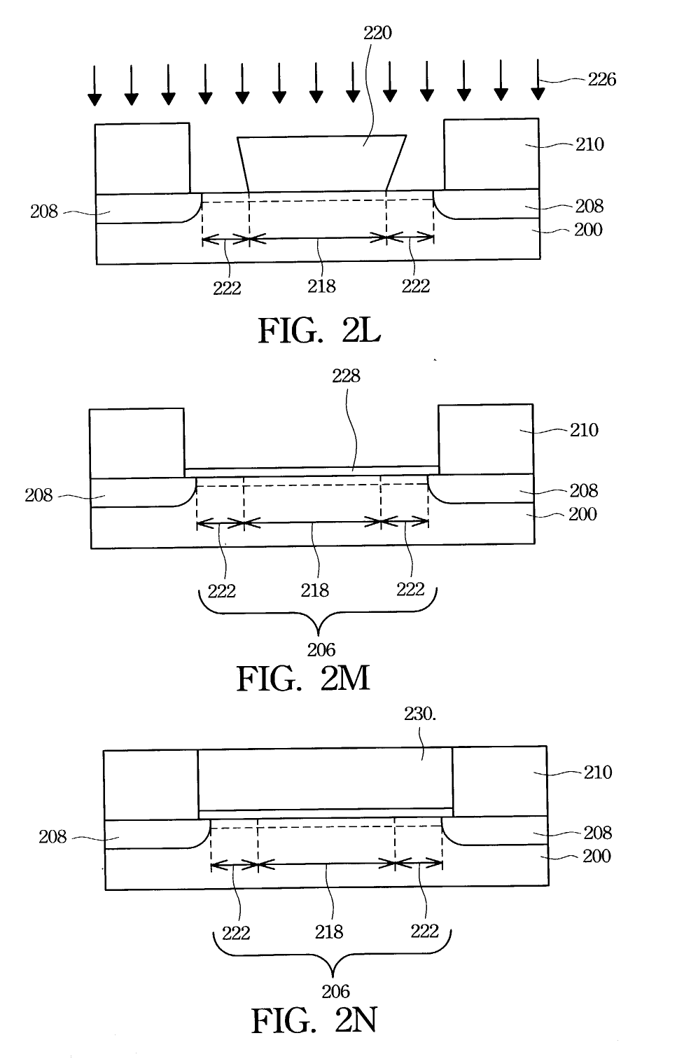

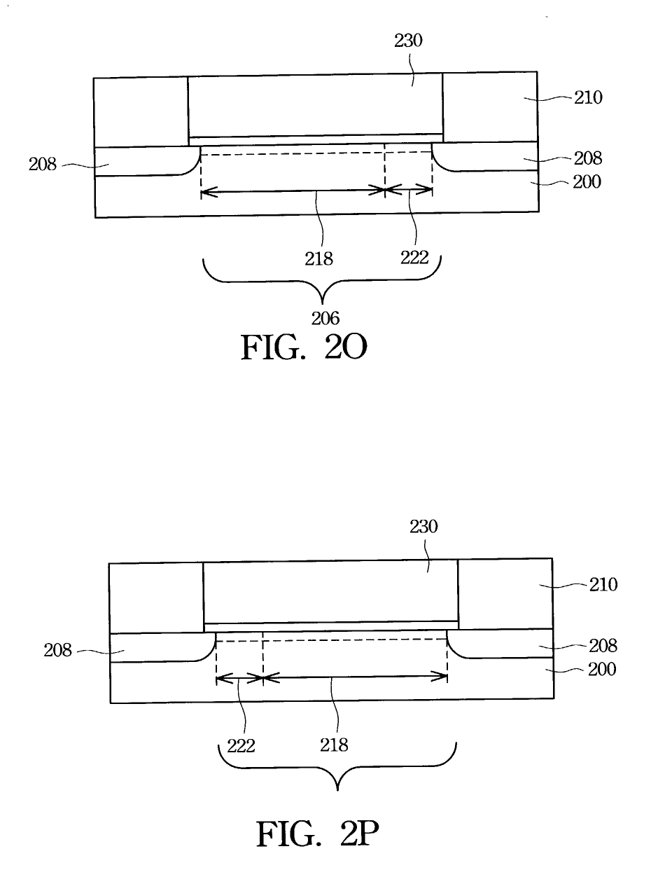

FIGS. 2A-2P are schematic cross-sectional views of the formation process of a MOSFET with low leakage current according to the present invention.

### DETAILED DESCRIPTION OF THE PREFERRED EMBODIMENT

The present invention is directed to a MOSFET with low leakage current to improve the shortcomings of MOSFET used in the prior art for semiconductor processes. In the present invention, the channel of the MOSFET is divided into several portions. By adjusting a threshold voltage and length of these portions along the channel region, the leakage current and the drain current of the MOSFET can be mutually optimized. The present invention is suitable for a NMOS and a PMOS. To illustrate the present invention, an example of the NMOS is set forth in details as follows.

FIGS. 2A-2P are schematic, cross-sectional views illustrating the process by which a MOSFET with low leakage current is formed according to the present invention. In FIG. 2A, performing a first ion implantation 202 on a substrate 200 obtains a doping concentration of a first threshold voltage, in which the first threshold voltage can be adjusted by the doping concentration. In the preferred embodiment of the present invention, the dopant of the first ion implantation 202 includes boron (B) which has an implanting energy range of about 5 to 30 keV and an doping concentration range of about 1×10¹² cm⁻² to 3×10¹³ cm⁻².

Afterwards, a sacrificial layer 204 is formed on the substrate 200. For example, the formation of the sacrificial layer 204 includes a chemical vapor deposition (CVD) and the sacrificial layer 204 has a thickness range of about 500 to 3000 angstroms. Conducting lithography and etching processes on the sacrificial layer 204 defines a channel region 206. In the preferred embodiment of the present invention, the material of the sacrificial layer 204 includes nitrides, such as silicon nitrides (Si₃N₄) or oxynitrides (SiOₓN_{y}).

In FIG. 2B, a source/drain 208 formed on the substrate 200 near the channel region 206 is connected to the channel region 206, in which the dopant material of the source/drain 208 includes arsenic (As) and has a doping concentration range of about 1×10¹⁵ cm⁻² to 3×10 ¹⁶ cm⁻². In FIG. 2C, a first dielectric layer 210 formed on the substrate 200 and being higher than the sacrificial layer 204 has a thickness range of about 500 to 3000 angstroms. Thereafter, a portion of the first dielectric layer 210 is removed to expose the sacrificial layer 204. For example, chemical mechanical polishing (CMP) or etching back is used to remove the portion of the first dielectric layer 210.

In FIG. 2D, the sacrificial layer 204 is stripped to form an opening 212 on the first dielectric layer 210 and to expose the channel region 206. Additionally, the first ion implantation 202 can also be performed after this step. In FIG. 2E, a second dielectric layer 214 is formed on the first dielectric layer 210 and the channel region 206 to fill the opening 212 in the channel region 206. The second dielectric layer 214 preferably has a thickness range of about 200 to 2000 angstroms.

In FIG. 2F, conducting an anisotropic etching process on the second dielectric layer 214 generates spacers 216 adjacent to the opening 212 in the channel region 206 and a first region 218 of the channel region 206 is exposed. In FIG. 2G, a third dielectric layer 220 is fabricated on the first dielectric layer 210, the spacers 216 and the first region 218. In FIG. 2H, a portion of the third dielectric layer 220 is removed and a top portion of the spacers 216 is exposed.

In FIG. 21, the spacers 216 are removed, in a process such as an etching step, to expose another portion of the channel region 206, in which the exposed portion is defined as a second region 222. The second region 222 separates the first region 218 from the source and the drain 208. In the preferred embodiment of the present invention, a photoresist 224a is formed on the first dielectric layer 210, the third dielectric layer 220 and the source/drain 208, which is followed by a lithography process to expose the second region 222 near the drain. Similarly, in FIG. 2K, a photoresist 224b layer is formed on the first dielectric layer 210, the third dielectric layer 220 and the source/drain 208. Afterwards, after performing a lithography process, the second region 222 adjacent to the source is exposed.

In FIG. 2L, a second ion implantation 226 is performed on FIG. 2I-2K and another portion of the channel region 206 is exposed. The second region 222 to which the source/drain 208 is adjacent has a second threshold voltage. More importantly, the first threshold voltage of the first region 218 is smaller than the second threshold voltage of the second region 222. The second region 222 is located between the first region 218 and the source/drain 208. In FIG. 2M, the third dielectric layer 220 is removed and a gate oxide layer 228 is formed on the channel region 206 of the exposed substrate 200.

In FIG. 2N, a conductive layer 230 formed on the gate oxide layer 228 and the first dielectric layer 210 is higher than the first dielectric layer 210. Subsequently, a portion of the conductive layer 230 is removed to expose the first dielectric layer 210 to generate a MOSFET with low leakage current. In FIG. 20, the second region 222 preferably neighbors with the drain, and the second region 222 preferably adjoins the source in FIG. 2P.

In the present invention, due to the first and the second ion implantation 226, the second region 222 has a higher doping than the first region 218 so that the second threshold voltage is higher than the second threshold voltage. Therefore, a depletion region reduction of the second region 222 decreases the subthreshold leakage current of the MOSFET. Also, by adjusting the length of the second region 222 along the channel region 206, the effect of the second threshold voltage imposed on the drain current can be effectively reduced such that the variation of the drain current is optimal, as shown in FIG. 2N.

Moreover, by changing the position of the second region 222 and adjusting the relative position between the second region 222 and the source/drain 208, the effective channel length of the second region 222 along the channel region 206 is allowed to be properly increased. Consequently, the effective channel length of the present invention is larger than that of the conventional structure. Further, the leakage current is adjusted to optimize the desired design of the drain current, as shown in FIG. 20 and 2P.

Specifically, if a bias voltage is applied to the drain and the source has no bias voltage, the depletion region near the source along the channel region 206 is smaller than that near the drain.

The channel region 206 in the present invention is divided into several portions, such as two or three portions. The single portion in the prior art is substituted with the portions of the present invention. Furthermore, due to an implantation of the anti-punch through in the second region 222, the depletion region of the second region 222 is further reduced to increase the effective channel region 206.

According to the above-mentioned, the present invention utilizes a MOSFET with low leakage current. The channel region of the MOSFET is divided into several portions with a variety of doping concentrations. By adjusting the threshold voltage, length and the position of the portions, the leakage current and the drain current are mutually optimized. Further, the second region having a higher threshold voltage is able to solve the problems of leakage current in the prior art. Therefore, the adjustment of the threshold voltage and length of these portions can increase the design flexibility of the MOSFET.

As is understood by a person skilled in the art, the foregoing preferred embodiments of the present invention are illustrative rather than limiting of the present invention. It is intended that various modifications and similar arrangements be included within the spirit and scope of the appended claims, the scope of which should be accorded the broadest interpretation so as to encompass all such modifications and similar structure.

What is claimed is:

1. A method for forming a MOSFET with low leakage current, the method comprising the steps of:
performing a first ion implantation into a substrate so that the substrate has a first threshold voltage;
forming a sacrificial layer on the substrate to define a channel region;
forming a source/drain on the substrate, wherein the source/drain is coupled to the channel region, respectively;
forming a first dielectric layer on the substrate and the sacrificial layer;
removing a portion of the first dielectric layer to expose the sacrificial layer;
removing the sacrificial layer so that the first dielectric layer includes an opening and exposes the channel region;
forming a second dielectric layer on the first dielectric layer and the channel region;
performing an anisotropic etching on the second dielectric layer to form a plurality of spacers adjacent to the opening and to expose a first region of the channel region;
forming a third dielectric layer on the first dielectric layer, the spacers and the first region;
removing a portion of the third dielectric layer to expose a portion of the spacers;
removing the spacers to expose a second region of the channel, wherein the second region is adjacent to the first region;
performing a second ion implantation into the second region so that the second region has a second threshold voltage, wherein the first threshold voltage of the first region is smaller than the second threshold voltage of the second region;
removing the third dielectric layer;
forming a gate oxide layer on the exposed substrate; and
forming a conductive layer on the gate oxide layer and the first dielectric layer.

2. The method of claim 1, after the step of removing the spacers, further comprising:
forming a photoresist layer on the first dielectric layer, the third dielectric layer and the source/drain; and
performing a lithography process to expose the second region coupled to the drain.

3. The method of claim 1, wherein the first ion implantation and the second ion implantation use a same dopant.

4. The method of claim 2, wherein the same dopant comprises boron.

5. The method of claim 1, wherein the first ion implantation has a concentration range of about 1×10¹² cm⁻² to 3×10¹³ cm⁻².

6. The method of claim 1, wherein the second ion implantation has a concentration range of about 1×10¹² cm⁻to 3×10¹³ cm⁻².

7. The method of claim 1, wherein a material of the sacrificial layer comprises silicon nitrides or oxynitrides.

8. The method of claim 1, wherein the sacrificial layer has a thickness range of about 500 to 3000 angstroms.

9. A method for forming a MOSFET with low leakage current, the method comprising the steps of:
forming a sacrificial layer on a substrate to define a channel region;
forming a source/drain on the substrate, wherein the source/drain is coupled to the channel region, respectively;
forming a first dielectric layer on the substrate and the sacrificial layer;
removing a portion of the first dielectric layer to expose the sacrificial layer;
removing the sacrificial layer so that the first dielectric layer includes an opening and exposes the channel region;
performing a first ion implantation into the substrate so that the substrate has a first threshold voltage;
forming a second dielectric layer on the first dielectric layer and the channel region;
performing an anisotropic etching on the second dielectric layer to form a plurality of spacers adjacent to the opening and to expose a first region of the channel region;
forming a third dielectric layer on the first dielectric layer, the spacers and the first region;
removing a portion of the third dielectric layer to expose a portion of the spacers;
removing the spacers to expose a second region of the channel, wherein the second region is adjacent to the first region;
performing a second ion implantation into the second region so that the second region has a second threshold voltage, wherein the first threshold voltage of the first region is smaller than the second threshold voltage of the second region;
removing the third dielectric layer;
forming a gate oxide layer on the exposed substrate; and
forming a conductive layer on the gate oxide layer and the first dielectric layer.

10. The method of claim 9, after the step of removing the spacers, further comprising:
forming a photoresist layer on the first dielectric layer, the third dielectric layer and the source/drain; and
performing a lithography process to expose the second region coupled to the drain.

11. The method of claim 9, wherein the first ion implantation and the second ion implantation use a same dopant.

12. The method of claim 10, wherein the same dopant comprises boron.

13. The method of claim 9, wherein the first ion implantation has a concentration range of about 1×10¹² cm⁻² to 3×10¹³ cm⁻².

14. The method of claim 9, wherein the second ion implantation has a concentration range of about 1×10¹² cm⁻² to 3×10¹³ cm⁻².

15. The method of claim 9, wherein a material of the sacrificial layer comprises silicon nitrides or oxynitrides.

16. The method of claim 9, wherein the sacrificial layer has a thickness range of about 500 to 3000 angstroms.

17. A MOSFET with low leakage current, the MOSFET comprising:
a substrate;
a channel region positioned in the substrate and including a first region a second region, wherein the first region is coupled to the second region, the first region has a first threshold voltage and the second region has a second threshold voltage, and the first threshold voltage is smaller than the second threshold voltage;
a source/drain located in the substrate and being adjacent to a sidewall of the channel region;
a gate oxide layer covering the channel region and being adjacent to the source/drain; and
a conductive layer covering the gate oxide layer on the channel region.

18. The MOSFET of claim 17, wherein the second region is adjacent to the drain.

19. The MOSFET of claim 17, wherein the second region is adjacent to the source.

20. The MOSFET of claim 17, wherein the first region comprises a first doping.

21. The MOSFET of claim 20, wherein the second region comprises a second doping.

22. The MOSFET of claim 21, wherein the first doping and the second doping comprises a same dopant.

23. The MOSFET of claim 22, wherein the same dopant comprises boron.

24. The MOSFET of claim 21, wherein the first doping has a concentration range of about 1×10¹⁷ cm⁻² to 3×10¹⁸ cm⁻².

25. The MOSFET of claim 21, wherein the second doping has a concentration range of about 2×10¹⁷ cm⁻² to 3×10¹⁸ cm⁻².

26. The MOSFET of claim 17, wherein a material of the sacrificial layer comprises silicon nitrides or oxynitrides.

27. The MOSFET of claim 17, wherein the sacrificial layer has a thickness range of about 500 to 3000 angstroms.
